(19) United States
(12) Patent Application Publication
(10) Pub. No.: US 2007/0155131 A1
(43) Pub. Date: Jul. 5, 2007

(54) Method of singulating a microelectronic wafer

(75) Inventor: Andrew N. Contes, Chandler, AZ (US)

Correspondence Address: INTEL CORPORATION;c/o INTELLEVATE, LLC, P.O. BOX 52050, MINNEAPOLIS, MN, 55402, US

(73) Assignee: Intel Corporation

(21) Appl. No.: 11/315,834

(22) Filed: Dec. 21, 2005

(51) Int. Cl. H01L 21/30

(52) U.S. Cl. 438/458; 257/E21.238

(57) ABSTRACT

A method of singulating a microelectronic wafer. The method comprises: providing a microelectronic wafer; focusing a laser beam in an interior region of the wafer from the backside of the wafer to form a modified region extending along the severance lines of the wafer dividing the wafer IC chips, the modified region further extending from an undersurface of the active surface and ending at a predetermined depth with respect to the backside. The modified region comprises a plurality of modified sites of the wafer molten by the laser and resolidified. The method further includes reducing a thickness of the wafer in a direction from the backside toward the active surface by a reduction amount equal to at least the predetermined depth; and dividing the wafer into individual IC chips along the severance lines at the modified sites.

### FIELD OF THE INVENTION

Embodiments of the present invention relate to a method of singulating a wafer.

### BACKGROUND OF THE INVENTION

Singulating microelectronic wafers, also known as dicing or die separation, is the process of cutting a microelectronic substrate having integrated circuit chips or “IC” chips formed thereon into individual microelectronic dice. Currently, although a number of methods for singulating microelectronic wafers are known, the most commonly used methods involve cutting the wafer along scribe or severance lines (commonly termed “streets”) on an active surface of the wafer with a rotating circular abrasive saw blade or dicer.

One way to singulate microelectronic wafers is to use a method called dicing-before-grinding, or a dice before grind (DBG) method, typically used on 200 mm diameter wafers usually made of bulk silicon and a combination of copper and aluminum for the circuit layers. According to the DBG method, a microelectronic wafer is cut as a bare wafer along streets to a predetermined depth, rather than over the full thickness of the microelectronic wafer, to form grooves along the streets on the face of the microelectronic wafer. After formation of the grooves, the wafer is placed on a backgrinding tape which adheres is to the active surface of the wafer. Thereafter, the backside of the wafer is ground to make the thickness of the microelectronic wafer not more than the depth of the grooves, for example, about 50 microns, thereby dividing the microelectronic wafer into individual rectangular regions. Thereafter, a dicing tape is attached to the backside of the wafer, and the backgrinding tape is removed from the active surface of the wafer using a method such as UV irradiation. The individual chips can then be machine-picked from the dicing tape, such as with an industrial vacuum picking tool.

Disadvantageously, the DBG method is not applicable to wafers comprising a low k material, such as wafers typically having a diameter of 300 mm or above, without substantial costly, complicated, and sometimes unreliable modifications to the DBG tools. For example, for wafers including carbon doped oxides (i.e.: SiO2+C) which make the dielectric layers more brittle, the existing DBG method involving a sawing of a bare wafer is no longer workable, to the extent that the low k materials too brittle to allow a bare wafer saw process, and are susceptible to chipping, breakage and cracking as a result. Thus, a DBG method would necessitate a mounting of the wafer to a dicing tape twice: once during the coat/scribe/saw process, and once again during actual singulation. However, since wafers including low k materials are typically brittle, a removal of the grooved wafer from the dicing tape to allow backgrinding could easily lead to wafer damage. The necessity to mount a low k wafer to a dicing tape on two occasions during a DBG process flow is additionally disadvantageous to the extent that it requires dicing tape on two occasions, and that it thus complicates wafer singulation, adding to manufacturing costs and negatively affecting throughput efficiency.

Another prior art method of singulating a wafer such as a wafer involves a laser processing method typically referred to as Backside Laser Cleavage, or “BLC.” The BLC method involves the application of a pulse laser beam capable of passing through the wafer with its focusing point set to the inside of the area to be divided. In BLC, the backside of the wafer to be singulated is first subjected to backgrinding and then polished to a roughness of typically less than about 0.05 micron.m with a polishing tool. Thereafter, a pulse laser beam is used from the backside of the wafer to continuously form a series of modified layers inside the wafer, each layer typically consisting of a plurality of modification sites usually about 50 microns thick, the layers extending from the active surface of the wafer to the backside of the wafer in a superimposed manner. The deterioration sites are provided along the severance lines formed in a lattice pattern on the active surface of the wafer. Then, the wafer is mounted onto a dicing tape, and singulated, such as by expanding the dicing tape according to known methods. Disadvantageously, the BLC process does not always lead to a reliable separation of all of the dice on the wafer. The prior art fails to provide a reliable and effective way of singulating wafers, especially wafers comprising a low k material.

### BRIEF DESCRIPTION OF THE DRAWINGS

FIG. 1 shows a perspective view of a conventional microelectronic wafer; and

FIGS. 2-8 show stages in the singulation of a microelectronic wafer according to a method embodiment.

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a method embodiment of singulating a wafer is disclosed. Reference is made to the accompanying drawings within which are shown, by way of illustration, specific embodiments by which the present invention may be practiced. It is to be understood that other embodiments may exist and that other changes may be made without departing from the scope and spirit of the present invention.

The terms on, above, below, and adjacent as used herein refer to the position of element relative to other elements. As such, a first element disposed on, above, or below a second element may be directly in contact with the second element or it may include one or more intervening elements. In addition, a first element disposed next to or adjacent a second element may be directly in contact with the second element or it may include one or more intervening elements.

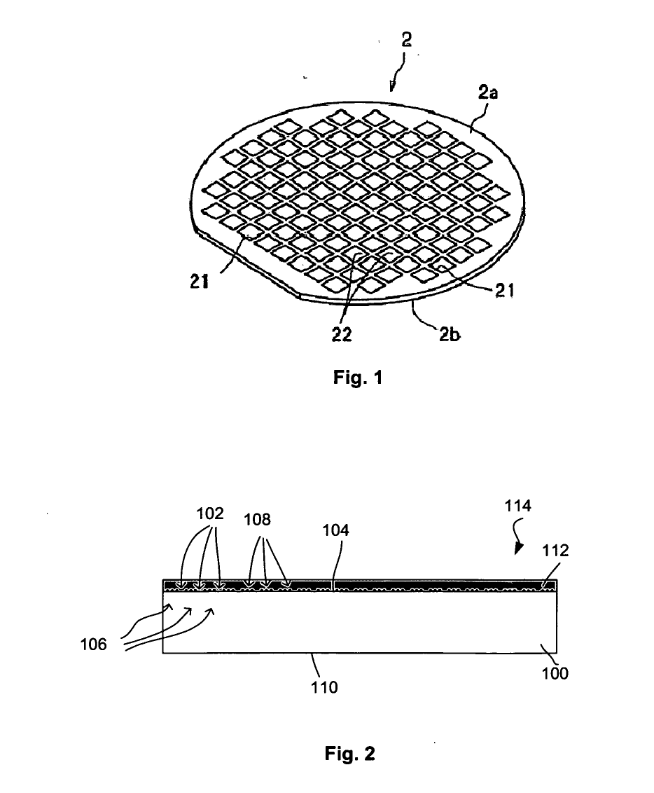

Referring first to FIG. 1, a perspective view of a conventional microelectronic wafer to be divided is shown. Wafer 2 shown in FIG. 1 may be made of a silicon wafer having a plurality of “streets” or severance lines 21 formed in a lattice pattern on the active surface 2a, and integrated circuit chips 22 are formed as function elements in a plurality of areas sectioned by the plurality of severance lines 21. Wafer 2 has a backside 2b opposite the active surface as shown.

FIGS. 2-8 show stages of singulating a wafer according to a method embodiment. FIGS. 2-8 show the stages being performed on a wafer 100 similar to wafer 100. As seen for example in FIG. 2, wafer 100 shown includes a plurality of severance lines 102 formed in a lattice pattern, similar to the lattice pattern of wafer 100 of FIG. 1, on the active surface 104. Wafer 100 further includes IC chips 106 having conductive bumps 108 disposed at the active surface for flip chip mounting subsequent to singulation. Wafer 100 has a backside 110 opposite the active surface as shown.

Referring now in particular to FIG. 2, a stage of singulating a wafer according to an embodiment comprises providing a protective member onto the active surface of the wafer. Thus, as seen in FIG. 2, a protective member 112 may be provided onto wafer 100 as shown to provide a combination wafer-protective member 114. Protective member 112 may comprise, by way of example, a suitable plastic backgrinding tape, and may be applied using a suitable tape applicator as well known among persons skilled in the art. Preferably, the protective member is a backgrinding tape adapted to exhibit a lowered tackiness as a result of UV irradiation. The protective member is provided to protect the IC chips on the active surface of the wafer and allows a securing of the wafer onto a chuck during an optional polishing and a subsequent backgrinding of the same.

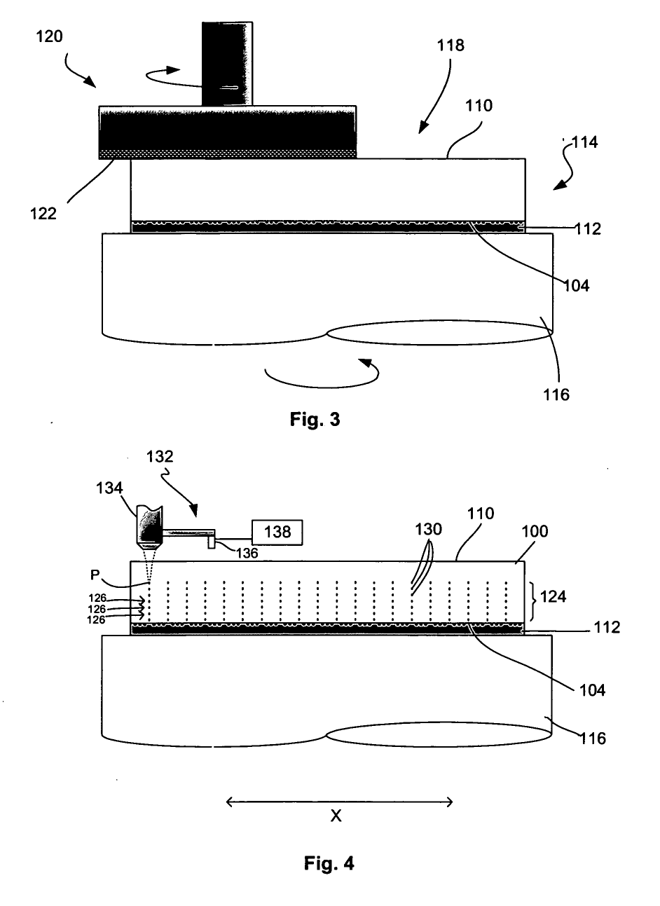

Referring next to FIG. 3 by way of example, a method embodiment comprises first polishing a backside 110 of wafer 100 as shown after providing a protective member. Polishing may be carried out to prevent a diffused reflection of an infrared laser beam applied from the backside 110 of the wafer 100 during a subsequent alignment stage to be described further below. That is, where an infrared laser beam is applied with its focusing point set to the inside of a wafer formed from silicon and the like, if the surface exposed to the infrared laser beam is rough, the infrared laser beam tends to be reflected on the surface diffusedly and does not reach a predetermined focusing point, thereby making it difficult to effect alignment of the modified sites with the wafer's severance lines, as will be described further below. Polishing may be carried out by using a polishing arrangement such as that in the embodiment shown in FIG. 3. Thus, when polishing, the combination wafer-protective member 114 may be placed on its protective member side onto a the chuck table 116 of the polishing machine 118 (therefore, the backside 110 of the wafer 100 faces away from the chuck table) as shown in FIG. 3, and the wafer-protective member combination 114 may be suction-held on the chuck table 116 by a suction means (not shown). A polishing tool 120 having a polishing wheel 122, which may be manufactured by dispersing abrasive grains such as zirconia oxide or the like into a soft member such as felt, etc., and fixing them with a suitable adhesive, may, by way of example, be rotated at 6,000 rpm and be brought into contact with the backside 110 of the wafer 100 while the chuck table 116 is rotated at 300 rpm, for example, to polish the back surface 110 of the wafer 100. During polishing, the backside 110 of the wafer 100 to be further processed may be polished to a surface roughness (Ra) specified by of about 0.05 micron.m or less (Ra≦0.05 micron.m), preferably about 0.02 micron.m or less (Ra≦0.02 micron.m).

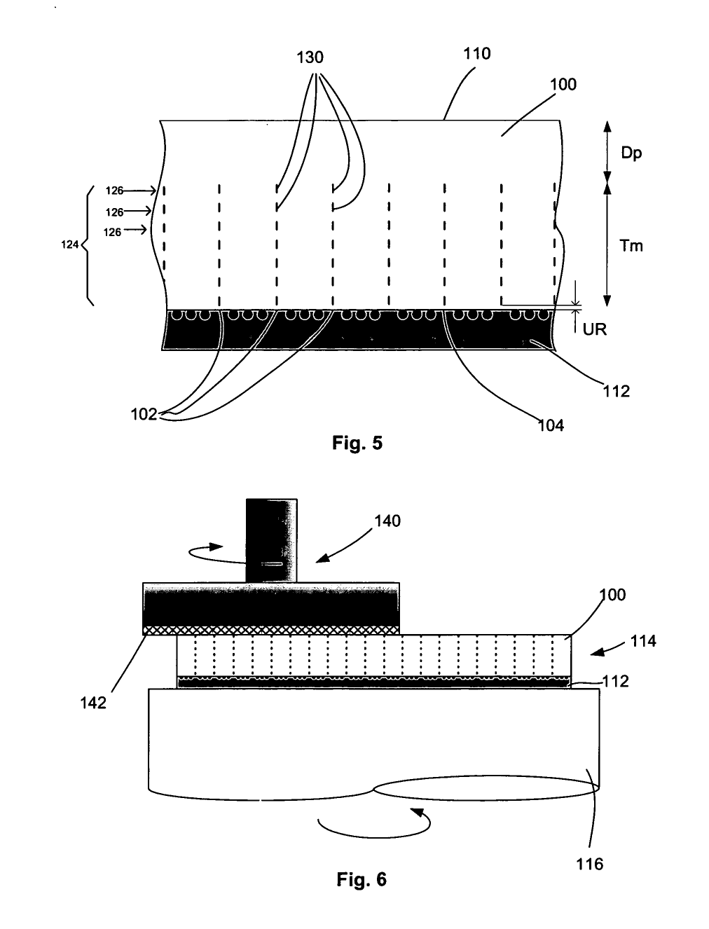

Next, as seen in FIGS. 4 and 5 by way of example, embodiments comprise the provision of a modified region in an interior region of the wafer. The modified region comprises a plurality of modified sites of the wafer molten by the laser and resolidified, and preferably includes at least one modified layer within the wafer. A melting and resolidification of the wafer material for each modification site takes place according to embodiments along the severance lines of the wafer, and is effected by using a laser beam, such as a pulse laser beam. According to a preferred embodiment, the at least one modified layer includes a plurality of modified sites formed along severance lines of the wafer, and further extends from an undersurface region of the active surface and ends at a predetermined depth with respect to the wafer backside. Referring now to FIGS. 4 and 5 in particular, a modified region 124 includes, in the shown embodiment, a plurality of superimposed modified layers 126. Each modified layer 126 comprises a row of modified sites 130, each layer extending in a direction parallel to a backside 110 or to an active surface 104 of the wafer 100. Referring now to FIG. 5, the modified sites 130 of each layer are formed at locations corresponding to severance lines 102 on the active surface 104 of the wafer 100. In addition, according to embodiments, the modified region 124 extends from an undersurface region of the active surface and ends at a predetermined depth Dp with respect to the backside 110. The predetermined depth Dp may typically measure from about 10 microns to about 25 microns, and is a function of the wafer thickness. Other factors which may determine the placement of the modification layers include throughput, direction of break, and laser processing parameters. The “undersurface region” as referred to herein corresponds to a region of the wafer that is disposed at least at a distance UR from the active surface of the wafer corresponding to a thickness of the wafer dielectric layers. Preferably, UR is between about 15 microns and about 30 microns from the active surface of the wafer. Disposing the modified region at a distance UR from the active surface, as opposed to at the active surface itself, would advantageously prevent a full singulation of the wafer during a subsequent backgrinding stage, in this way preventing a shifting of the IC chips during backgrinding, as will be apparent as the description progresses. In addition, disposing the modified region at a distance UR from the active surface ensures an active surface on which irregularities, such as those that would exist should the modified region begin at the active surface, are minimized, in this way ensuring an improved adhesion of the protective member to the active surface. A thickness Tm of the modified region is a function of the thickness of the wafer to be singulated. For a modified region including a plurality of modified layers, the thickness of the modified region is in turn a function of the number of layers to be provided. For example, for a wafer having a thickness of about 125 microns, about four modification layers may be provided to ensure subsequent singulation, while for a wafer having a thickness of about 225 microns, about seven to eight modification layers may be necessary. The modified sites of each modified layer correspond to molten and then re-solidified regions of the wafer, the melting taking place as a result of the focused application of a laser beam, such as a pulse laser beam.

Referring still to FIGS. 4 and 5 by way of example, a formation of the modified region according to embodiments comprises focusing a laser beam in an interior region of the wafer from the backside of the wafer. As seen in particular in FIG. 4, focusing a laser beam in an interior region of the wafer according to embodiments comprises applying to the wafer a laser beam capable of passing through the wafer from the backside 110 of the wafer 100, and focusing the beam at a plurality of focusing points, such as focusing point P, along the wafer's severance lines. This modified layer formation stage is carried out by using a laser beam application device 132 shown schematically in FIG. 4. The laser beam application device 132 comprises a laser beam condenser 134 adapted to focus a laser beam, such as, for example, a pulse laser beam, at an interior region of the wafer held on the chuck table 116. Device 132 may further include, according to an embodiment, and an image pick-up device 136 for picking up an image of the wafer held on the chuck table 116. The chuck table 116 may be configured to move the suction-held wafer in a processing-feed direction indicated by an arrow X and an indexing-feed direction perpendicular to arrow X and to the page containing FIG. 4, as would be recognized by one skilled in the art. The image pick-up device 136 of the above laser beam application device 132 may comprise an infrared illuminating device to apply infrared radiation to the wafer, an optical system to capture infrared radiation applied by the infrared illuminating device, and an image pick-up device (infrared CCD) to output an electric signal corresponding to infrared radiation captured by the optical system, in addition to an ordinary image pick-up device (CCD) for picking up an image with visible radiation in the illustrated embodiment. An image signal is transmitted to a control means that will be described hereinafter.

In the modified layer formation stage as shown by way of example in FIG. 4, the protective member 3 side of the wafer 100 whose backside 110 may, according to an embodiment, have been polished as shown by way of example in FIG. 3, remains on the chuck table 116 as shown in FIG. 4. The chuck table 116 suction-holding the wafer 100 may be brought to a position right below the image pick-up device 136 by a moving mechanism (not shown). After the chuck table 116 is positioned right below the image pick-up device 136, alignment work for detecting the area to be processed of the wafer 100 may, according to an embodiment, be carried out by using the image pick-up device 136 and the control means 138 as shown in FIG. 4. The image pick-up device 136 and the control means 138 may thus carry out image processing such as pattern matching, etc., to align a severance lines 102 formed in a predetermined direction of the wafer 100 with the condenser 134 of the laser beam application device 132 for applying a laser beam along the severance lines 102, thereby performing the alignment of a laser beam application position. The alignment of the laser beam application position is also carried out on severance lines 102 that are formed on the wafer 100, and extends in a direction perpendicular to the above predetermined direction. Although the active surface 104 on which the severance lines 102 of the wafer 100 are formed faces toward the chuck table at this point, the image pick-up device 136 may, by way of example, include an infrared illuminating device, an optical system for capturing infrared radiation and an image pick-up device (infrared CCD) for outputting an electric signal corresponding to the infrared radiation as described above. Therefore, an image of the severance lines 102 can be taken through the backside 110, as would be within the knowledge of one skilled in the art. The arrangement relating to the image pick-up device 136 and its operation is within the knowledge of one skilled in the art.

After the severance lines 102 formed on the wafer 100 held on the chuck table 116 are detected and the alignment of the laser beam application position is carried out as described above, the chuck table 116 may be moved to a laser beam application area where the condenser 134 of the laser beam application device 132 for applying a laser beam may be located so as to focus a laser beam, such as a pulse laser beam, from condenser 134 at predetermined locations corresponding to the modified sites to be provided, in an interior region of the wafer 100. Application of the laser beam results in the formation of modified layers 126. Each modified site corresponds to a molten-solidified site of the wafer. By forming the modified layers 126, the wafer 100 can be easily divided by exerting external force along the modified layers 126. When a plurality of superimposed modified layers such as layers 126 are to be provided in a wafer, the focusing point P of the laser beam may be moved in a stepwise fashion in a thickness direction of the wafer from one modified layer to a level of a next modified layer to be formed. It is noted that, to the extent that the laser beam is focused according to embodiments in an interior region of the wafer, after provision of the modified region by way of laser processing, neither the backside of the wafer nor the active surface of the wafer show any signs of modification after the laser processing stage.

Referring next to FIG. 6 by way of example, a next stage of singulating a wafer according to embodiments comprises reducing a thickness of the wafer in a direction from the backside toward the active surface by a reduction amount equal to at least the predetermined depth Dp. Thus, referring now to FIG. 6, according to an embodiment, the combination wafer-protective member 114 may still be held on chuck table 116 and subjected to backgrinding for example using a backgrinding tool 140 having a backgrinding wheel 142. According to one embodiment, the chuck table 116 may rotate counter to a rotation direction of the wheel 142 in a well known manner. Backside 110 of the combination 114 may, according to an embodiment, first be rough ground, and then precision ground as would be recognized by one skilled in the art. An amount by which a thickness of the wafer may be reduced would be equal to or greater than Dp in order to reach the modified region 124. The wafer may, for example, be thinned down to a thickness of about 125 microns. Because the modified region is set at a distance UR with respect to the active surface, the thickness reduction stage would not lead to a shifting of the IC chips during backgrinding.

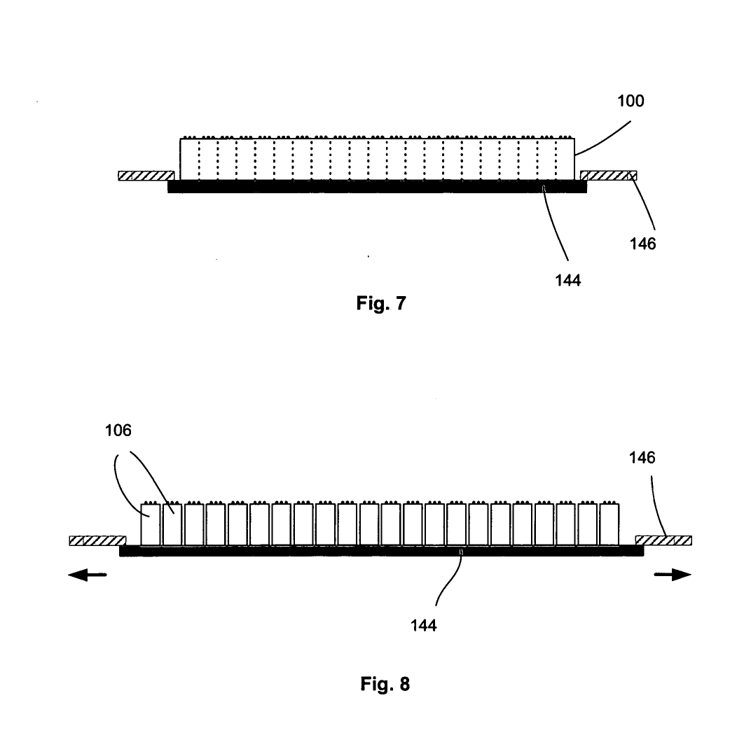

Referring next to FIGS. 7 and 8 by way of example, a next stage of singulating a wafer according to embodiments comprises dividing the wafer into individual IC chips along the severance lines and at the modified sites. According to the shown embodiment, dividing may include first placing the combination thinned wafer-protective member 114 including the modified region 124 on its backside 110 onto a dicing tape 144 mounted on a dicing frame 146, in a manner well known to a person skilled in the art. The protective member 112 may then be removed from the active surface 104 in a detaping process as would be well known to a person skilled in the art. In order to reduce a tackiness of the protective member for detaping, the protective member may be subjected to an external stimulus such as UV irradiation.

Referring next to FIG. 8, dividing according to embodiments may further include expanding the dicing tape 144 in order to effect a singulation of the wafer 100 by creating gaps 146 between the individual IC chips 106. Thus, as shown in FIG. 8, the dicing tape may be a stretch dicing tape, the expansion stage being carried out in a manner that would be within the knowledge of one skilled in the art. After division as shown by way of example in FIG. 8, the dicing tape may be subjected to an external stimulus, such as UV irradiation, in order to reduce a tackiness of the same. Thereafter, the individual IC chips may be picked up at a tape and reel die sort (TDRS) of a wafer die ejector (WDE), as would be recognized by one skilled in the art.

Embodiments are not limited by the method embodiment described above, and comprise within their scope among other things the provision of a modified region that consists of a single modified layer, a reduction in thickness of the wafer after provision of the modified region according to any one of the well known thickness reduction methods, and a division of the wafer into individual severance lines at the modified sites in any one of the well known manners, such as through a stretching process as described above, or, in the alternative, through a laser separation process, a bending process, or an ultrasonic dividing process, as would be within the knowledge of a person skilled in the art. In addition, embodiments comprise within their scope a molten region which includes modified sites disposed in columns in registration with the severance lines, where each site is substantially continuous along a thickness direction of the wafer.

Advantageously, embodiments allow a singulation of wafers including low k materials, and of wafers above 200 mm, such as 300 mm and above, without any modifications to existing tools, in a reliable, cost-effective manner that allows high throughput. In addition, embodiments provide a singulation method that reduces a manipulation of the wafer from dicing tape to backgrinding tape and back again onto a dicing tape as is the case with the prior art, thus simplifying the process, reducing a risk of damage to the wafer, and saving time and resources. By providing the modified region before reducing the thickness of the wafer, such as through grinding, the wafer is already held on a backgrinding chuck to go directly to the grind step, in this way alleviating the need to transfer the wafer from a dicing tape to a backgrinding tape back to a dicing tape, and increasing throughput. Moreover, advantageously, embodiments provide a potential for increased die break strength with respect to a stand alone BLC process as described in the Background section above. Furthermore, providing a modified region at a distance from the active surface advantageously prevents a shifting of the IC chips during backgrinding. In addition, disposing the modified region at a distance from the active surface ensures an active surface on which irregularities, such as those that would exist should the modified region begin at the active surface, are minimized, in this way ensuring an improved adhesion of the protective member to the active surface.

The various embodiments described above have been presented by way of example and not by way of limitation. Thus, for example, while embodiments disclosed herein teach the formation of embedded capacitors in build-up layer of a packaging substrate, other passive structures, such as for example inductors, resistors, etc., can similarly be formed and/or accommodated using one or more of the embodiments disclosed herein. Also, these passive components can be formed in any number of substrate types that can accommodate the incorporation TFC laminates.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A method of singulating a microelectronic wafer, comprising:
providing a microelectronic wafer having an active surface and a backside, the wafer further including a plurality of severance lines formed in a lattice pattern on the active surface thereof and a plurality of integrated circuit chips disposed in regions of the wafer sectioned by the severance lines;
focusing a laser beam in an interior region of the wafer from the backside of the wafer to form a modified region extending along the severance lines from an undersurface of the active surface and ending at a predetermined depth with respect to the backside, the modified region comprising a plurality of modified sites of the wafer molten by the laser and resolidified;
reducing a thickness of the wafer in a direction from the backside toward the active surface by a reduction amount equal to at least the predetermined depth; and
dividing the wafer into individual IC chips along the severance lines at the modified sites.

2. The method of claim 1, wherein the modified region includes at least one modified layer, the at least one modified layer comprising the plurality of modified sites along the severance lines,

3. The method according to claim 1, further comprising securing the active surface of the wafer onto a protective member before focusing.

4. The method of claim 1, wherein reducing comprises reducing a thickness of the wafer using backgrinding.

5. The method of claim 4, wherein backgrinding comprises rough grinding followed by precision grinding.

6. The method of claim 3, further comprising securing a combination of the wafer and protective member onto a holding chuck such that the backside of the wafer faces outward.

7. The method of claim 6, wherein the holding chuck comprises a vacuum chuck.

8. The method of claim 2, wherein the at least one modified layer comprises a plurality of superimposed modified layers each having modified sites provided along severance lines on the active surface.

9. The method of claim 1, wherein focusing comprises focusing a pulse laser beam.

10. The method of claim 8, wherein focusing comprises changing a focusing point of the laser beam in a stepwise fashion in a thickness direction of the wafer to yield the superimposed modified layers.

11. The method of claim 1, wherein focusing comprises aligning a focal point of the laser beam to the severance lines by capturing an image of the severance lines through the backside using an aligning system including an infrared illuminating device.

12. The method of claim 1, further comprising polishing a surface of the backside before focusing.

13. The method of claim 12, wherein polishing comprises polishing to a roughness less than or equal to about 0.05 microns.

14. The method of claim 1, further comprising:
after reducing, securing a backside of the wafer to a dicing tape mounted onto a dicing frame; and
after dividing, releasing the wafer from the dicing tape.

15. The method of claim 14, further comprising:
securing the active surface of the wafer onto a protective member before focusing; and
removing the protective member after securing the backside; and

16. The method of claim 15, wherein at least one of removing the protective member and releasing the wafer form the dicing tape comprises using a UV irradiator to reduce a tackiness of the tape.

17. The method of claim 14, wherein the dicing tape is a stretch dicing tape, and wherein dividing comprises expanding the stretch dicing tape to create gaps between adjacent integrated circuit chips of the wafer.

18. The method of claim 1, wherein dividing comprises using of a stretch dividing device, a bending dividing device, an ultrasonic dividing device and a laser dividing device.

19. The method of claim 1, wherein the undersurface is between about 15 microns and about 30 microns from the active surface.

20. The method of claim 1, wherein the predetermined depth is about is between about 10 microns and about 25 microns.
